(19) United States
(12) Patent Application Publication
(10) Pub. No.: US 2013/0010418 A1
(43) Pub. Date: Jan. 10, 2013

(54) MODULAR, ALL-IN-ONE COMPUTING DEVICE

(76) Inventors: Tomas J. Flynn, Magnolia, TX (US); Dennis Baker, Houston, TX (US); Valentin Popescu, Tomball, TX (US); Roger Cao, Tomball, TX (US)

(21) Appl. No.: 13/520,225

(22) PCT Filed: Apr. 29, 2010
(86) PCT No.: PCT/US2010/032978

§ 371 Date: Jul. 2, 2012

(51) Int. Cl. G06F 1/16; H05K 13/04

(52) U.S. Cl. 361/679.21; 29/825

(57) ABSTRACT

An exemplary embodiment of the present invention provides a modular, all-in-one computing device. The modular, all-in-one computing device includes a computer module comprising a processor, a memory, a storage system, and an interface, wherein the computer module does not include a keyboard or a video display. The modular, all-in-one computing device also includes a display unit, configured to support the computer module, provide power to the computer module, and interface with the computer module.

### BACKGROUND

All-in-one computers generally incorporate a full computer system into a display device, providing a single unit. Peripheral devices, such as keyboards, speakers, and the like, can then be connected to the display device to provide a computer with a more convenient foot print. Further, setting up an all-in-one computer may be easier than a standard computer, since fewer cables and connectors are used.

However, an all-in-one computer may represent a substantial risk to a computer manufacturer, as the choice of the units incorporated into the device determines sales. Accordingly, if a processor becomes obsolete before the units are sold, the computer manufacturer may end up selling a large amount of inventory at a reduced cost. An all-in-one computer may also pose a risk to the purchaser, as the units are built in a single piece, providing no clear path for upgrades. In addition to these issues, the display may outlast the computer by several years, resulting in discarding a valuable display for a computer fault.

### BRIEF DESCRIPTION OF THE DRAWINGS

Certain exemplary embodiments are described in the following detailed description and in reference to the drawings, in which:

FIG. 1 is a diagram of an all-in-one computing device showing an installation of a computing module, in accordance with exemplary embodiments of the present invention;

FIG. 2 is a block diagram of a computing module, in accordance with exemplary embodiments of the present invention;

FIG. 3 is a drawing of a computing device that may be useful for signage or display applications, in accordance with exemplary embodiments of the present invention; and

FIG. 4 is a bracket for supporting a standard computing device, in accordance with exemplary embodiments of the present invention.

### DETAILED DESCRIPTION OF SPECIFIC EMBODIMENTS

Exemplary embodiments of the present invention provide a modular, all-in-one computing system in which a computing module may be paired with a display, for example, based on the intended application of the computing system. A modular, all-in-one computer may, thus, provide a convenient platform for implementing a thin client computing environment, a personal computing environment, or an electronic sign, among others.

In a thin client environment, a network server may provide a substantial amount of the computing power and storage used, for example, while running applications. In this environment, a local machine may provide mainly input and display functionality. Accordingly, in embodiments, a display or multiple displays, having an appropriate size for a desktop application, such as a 19 inch or a 22 inch monitor, among many others, may be selected. This display may be paired with a computing module that has sufficient power to support the thin client implementation selected. As an example, such a module may have 32 MB to 4 GB of memory and a relatively low power processor, such as a MARVELL ARM, a VIA EDEN, an INTEL ATOM, or an AMD TURION MOBILE, and the like. The local computer may not use substantial storage capacity, as data storage may be provided on the network servers. Thus, the computing module may have a flash drive or other small storage unit, such as a 2 GB flash ram, an 8 GB miniature hard drive, and the like. The storage system will mainly be used in a thin client computing environment to provide booting capabilities. One of ordinary skill in the art will recognize that the configurations listed above are merely examples. Any number of other configurations may also be used in embodiments.

Other applications may use a similar display, but pair the display with a module having greater computing power. For example, a personal computer generally runs applications locally. Further, many personal computer users store and process images and video. Thus, a computing module for these embodiments may have 2 GB to 16 GB of memory and a relatively powerful processor, such as an AMD ATHLON dual core, an INTEL CORE 2 DUO, an INTEL QUAD CORE, and the like. Further, the storage system for a personal computing system may be relatively large, such as a hard drive of 160 GB, 320 GB, 740 GB, or greater. As above, these configurations are merely exemplary, as any number of other configurations may also be used.

In an exemplary embodiment, the modular computing system is used to provide an electronic sign. In this application, a large, high resolution display, such as a 47 inch display, a 52 inch display, or an even larger display, may be paired with a relatively high power computing module. For example, the processor may be an AMD ATHLON dual core, an INTEL CORE 2 DUO, an INTEL QUAD CORE, and the like. The computing module may have 2 GB to 16 GB to support the display of complex video and image information. In contrast to the personal computer, the information to be displayed may be relatively repetitive and, thus, the storage system may be relatively small, for example, a 2 GB to 32 GB flash drive. The computing module for the sign application may use a wireless network to obtain content for display. Further, the computing module may have security and decoding devices to decode content and to prevent unauthorized access to the display. As above, these configurations are merely exemplary, as any number of other configurations may be used.

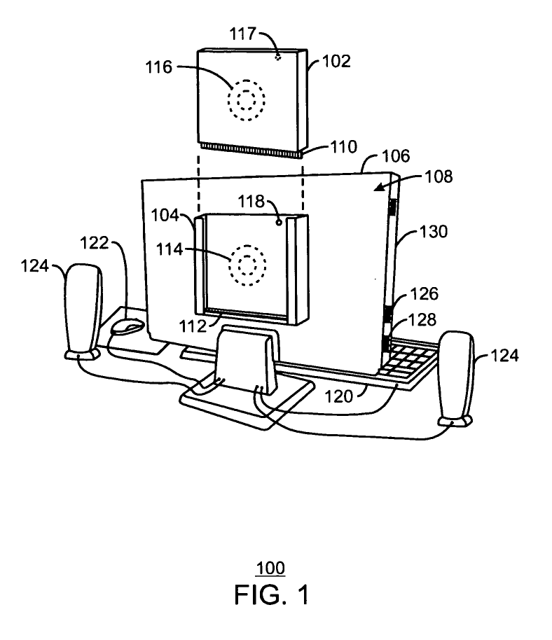

FIG. 1 is a drawing of a modular, all-in-one computing device 100 showing an installation of a computing module 102 in a bracket 104 on a display unit 106, in accordance with exemplary embodiments of the present invention. In this exemplary embodiment, the computing module 102 is configured to slide into the bracket 104 on a back surface 108 of the display 106. However, the computing module 102 is not limited to this configuration. In embodiments, the computing module 102 may snap into place on the display 106 or drop into a slot on the display 106 that leads to a connector 112 located inside the case of the display 106. A connector 110 may be configured to couple to a mating connector 112, located at the bottom of the bracket 104.

Power to the computing module 102 may be provided through the connector 110 from the mating connector 112 on the display 106. In other embodiments, power may be provided to the computing device 102 by an inductively coupled power unit located within the display 106. In this embodiment, after the computing module 102 is installed on the display 106, a inductively coupled power transmitter 114 on the display 106 may be located in proximity to a power receiver 116 on the computing module 102.

In embodiments, the connectors 110 and 112 may route video signals, keyboard and pointer information, touch screen information, network connections, and the like, between the computing module 102 and the display 106. In other embodiments, a high speed data link, such as a high speed serial connection, may route communications between the computing module 102 and the display 106. For example, after installation of the computing module 102 on the display 106, the lens 117 of a high speed optical transceiver unit in the computing module 102 may be located in proximity to a matching lens 118 of a high speed optical transceiver located within the display 106. In embodiments that use both an inductive coupled power unit and a high speed optical transceiver unit, the computing module 102 may be hermetically sealed to protect the electronics.

The display 106 may provide a central interface system for coupling to peripheral devices for the modular, all-in-one computing device 100. For example, input devices such as a keyboard 120 and a mouse 122 may be coupled to the display 106, with signals routed to the computing device 102 through the connectors 110 and 112. Other output devices, such as speakers 124, additional displays, and the like, may also be connected to the display 106. The display 106 may provide ports for other external devices, such as a universal serial bus (USB) port 126 or an external serial ATA disk drive (eSATA) port 128, among others. A DVD 130, or other optical drive systems, such as a CD ROM or a BluRay player, may be built into the case of the display 106. In addition to these units, the display 106 may have a touch screen input device. The modular, all-in-one computer is not limited to this configuration, as any number of units may be included depending on the application. For example, a thin client implementation may not have an optical drive system or ports for other external devices. Further, the display 106 may have video ports for driving other displays to enable a multiple display computing environment.

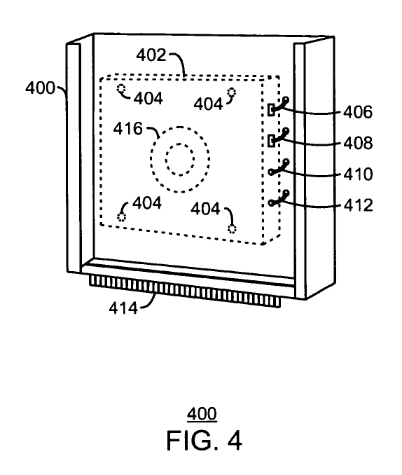

Together, the computing module 102 and display 106 provide a modular, all-in-one computing device 100 that may be tailored to the needs of an application. This may lower the risk of selling or purchasing these devices and potentially increase market penetration. The modular, all-in-one computing device 100 are not limited to customized computing modules 102. In some embodiments standard computing units may be used in implementations with an appropriate mounting device, as discussed with respect to FIG. 4.

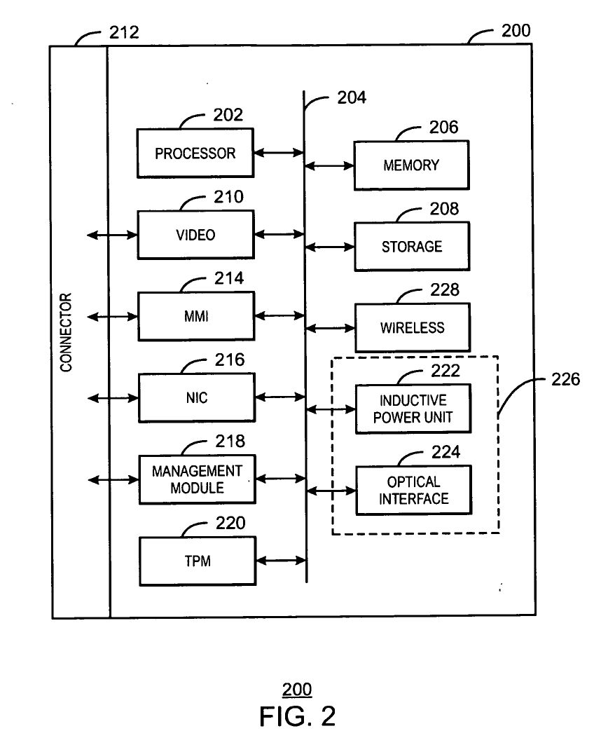

FIG. 2 is a block diagram of a computing module 200 that may be used in exemplary embodiments of the present invention. The computing module 200 can have a processor 202 that is coupled to a bus 204 to provide communications between units within the computing module 200. The computing module 200 can also have memory 206 and storage 208 coupled to the bus 204. The memory 206 may include random access memory (RAM), read only memory (ROM), or any combinations thereof. The storage 208 may include hard drives, flash drives, solid state drives, and the like. The processor 202, the memory 206, and the storage 208 may be selected based, at least in part, on the application for which the computing module 200 is intended, as discussed above. In exemplary embodiments, the computing module 200 is a full computer device designed to be accessed from a coupled display, wherein the display will have a coupled keyboard or mouse. Thus, the computing module 200 may have no built in keyboard, or other input device, and no built in display. The computing module 200 may have status indicators visible from the exterior, for example, LEDs to indicate that power and communications have been established between the computing module 200 and the display.

Instead, the computing module 200 may have a video interface 210 that provides a monitor signal, such as a RGB or DVI signal, to one or more displays through a connector 212. Other interfaces may also be coupled through the connector 212, including a man-machine interface (MMI) 214, The MMI 214 can provide an interface to keyboards, mice, and a touch screen, among others. A network interface card (NIC) 216 may be included to allow the computing module 200 to access a network through the connector 212. Further, in embodiments, a management module 218 coupled to a network through the connector 212 may allow external control of the computing module 200, which may be useful for thin clients and electronic signs, among others. The management module 218 may be coupled to a trusted platform module (TPM) 220, which can provide secure sign-in to the computing module 200, secure access to content, decoding services, encryption keys, and the like. The TPM 220 may be useful to prevent unauthorized access to displayed content, for example, in sign applications. The computing module 200 is not limited to the input/output interface units discussed above, as many other device interfaces may be included. Such device interfaces may include a sound interface to power speakers, a USB port interface, a Fire-wire port interface, and an eSATA interface, among many others.

The computing module 200 may be configured to obtain power over the connector 212. This may be useful for more powerful computing modules 200, such as in personal computers, which are likely to draw higher amounts of power, for example, 20W to 65W, or more. In other exemplary embodiments, the computing module 200 may be configured to obtain power through an inductively coupled power receiver 222. This configuration may be useful to provide power for less powerful computing modules 200, such as thin clients, which may draw 3.5W to 25 W, or more. However, the inductively coupled power units are not limited to these power levels or modules, as technological advances will allow increasing amounts of power to be transferred. Further, the power draw for higher power computing modules 200 may also decrease as technology advances. Accordingly, any computing module 200 configured to be powered from a display using an inductively coupled power system is considered to be within the scope of the present claims.

The computing module 200 may not need to use a connector 212, but may, instead, communicate with the display over a high speed serial link, for example, through an optical interface 224. In such exemplary embodiments, the display will have circuitry to decode or demultiplex the optical signals, and send each signal to the appropriate input or output device. Embodiments that include the remote power and interface devices 226 may not have other interface devices, for example, interface drivers 210, 214, 216, and 228, or connector 212, allowing the computing module 200 to be hermetically sealed. The computing module 200 is not limited to the interface units discussed above, as any number of other units may be included. For example, the computing module 200 may include a wireless network interface 228 that may follow any number of IEEE standards, such as the 802.11 standard, the 802.16 standard, a cellular data network, and the like. Further, the wireless network interface 228 may provide the computing module 200 with wireless wide area network communications capability or cellular telephone communications capability. Thus, a modular, all-in-one computer device may be configured for desktop applications, such as thin client or general purpose use, or for more dedicated applications, such as an electronic sign.

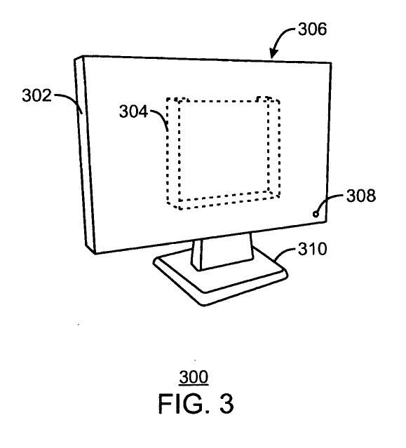

FIG. 3 is a drawing of a modular, all-in-one computing device 300 that may be useful for signs, in accordance with exemplary embodiments of the present invention. The modular, all-in-one computing device 300 includes a display 302 with a computing module 304 installed in a bracket on the back side 306 (opposite a display panel). The computing module 304 may be selected as described above. In embodiments, the display 302 may have a wireless device input, such as an infrared port 308, for use with wireless keyboards and pointing devices. This may allow the modular, all-in-one computing device 300 to be placed in a convenient location, such as in an elevated configuration, while allowing control. A large screen device, such as a modular, all-in-one computing device 300 used as a sign, may permit the use of a standard computing unit as the computing module 304. The modular, all-in-one computing device 300 may be supported by a stand 310 or may be hung from a wall using mounting brackets.

FIG. 4 is a mount 400 for coupling a standard computing unit 402, in accordance with exemplary embodiments of the present invention. In embodiments, the computing unit 402 (shown in dashed lines) may be a thin client personal computer (PC), for example, available from HP and other vendors. In other embodiments, the computing unit 402 may be a small form factor PC, available from HP and other vendors. In embodiments that use a large display, such as sign applications, the computing unit 402 may be a full size PC. The computing unit 402 may be attached to the mount 400 by a series of screws 404. The arrangement of the screws may be in a standard configuration, for example, complying with a video electronics standards association (VESA) standard arrangement. The mount 400 may be designed to mate to a corresponding bracket on the back of a display, such as the bracket 104 on the back of the display 106 discussed with respect to FIG. 1.

The mount 400 can include all of the connection cables used to provide power to the computing unit 402 and to route signals between the computing unit 402 and an attached display. In embodiments, the cables may include a power cable 406, a video cable 408, a keyboard cable 410, and a mouse cable 412. The cables that may be present are not limited to these, as any number of other cables may be provided to couple other devices to the display, including an Ethernet cable, a USB cable, a speaker cable, an eSATA cable, and the like. The cables may be wired through the mount 400 to a connector 414 that is configured to mate with a corresponding connector on a display, such as the mating connector 112 on the back of the display 106 discussed with respect to FIG. 1. In embodiments, the bracket 400 may include an inductively coupled power receiver 416 configured to obtain power for the computing unit 402 from an induction power transmitter located within the display. The inductively coupled power receiver 416 can be wired to the power cable 406 to provide power for the computing unit 402.

What is claimed is:

1. A modular, all-in-one computing device, comprising:
a computer module comprising a processor, a memory, a storage system, and an interface, wherein the computer module does not comprise a keyboard and the computer module does not comprise a video display; and
a display unit, wherein the display unit is configured to:
support the computer module;
provide power to the computer module; and
interface with the computer module.

2. The modular, all-in-one computing device of claim 1, wherein the display unit comprises an external bracket to hold the computer module.

3. The modular, all-in-one computing device of claim 1, wherein the computer module comprises an inductively coupled power receiver.

4. The modular, all-in-one computing device of claim 1, wherein the interface comprises a high speed serial interface.

5. The modular, all-in-one computing device of claim 1, wherein the computer module is hermetically sealed.

6. The modular, all-in-one computing device of claim 1, wherein the display unit comprises an inductively coupled power transmitter configured to power the computer module.

7. The modular, all-in-one computing device of claim 1, wherein the computer module comprises a video driver, a man-machine interface drive, and a network interface driver.

8. The modular, all-in-one computing device of claim 1, wherein the display unit comprises a connector configured to couple to the computer module.

9. The modular, all-in-one computing device of claim 1, comprising a thin client computer system.

10. The modular, all-in-one computing device of claim 1, comprising an electronic sign.

11. The modular, all-in-one computing device of claim 1, wherein the display unit comprises a touch screen.

12. A method of configuring a modular, all-in-one computing device, comprising:
receiving a first display unit with a first size and a first resolution;
receiving a first computer module with a first configuration, wherein the first computer module does not comprise a keyboard and the first computer module does not comprise a video display; and
coupling the first computer module to the first display unit to engage a power system and a communication system between the first display unit and the first computer module.

13. The method of claim 12, comprising:
receiving a new computer module comprising a second configuration;
removing the first computer module from the first display unit; and
coupling the new computer module to the first display unit to engage the power system and the communication system between the first display unit and the new computer module.

14. The method of claim 12, comprising:
receiving a new display unit comprising a second size, a second resolution, or both;
removing the first computer module from the first display unit; and
coupling the first computer module to the new display unit to engage the power system and the communication system between the new display unit and the first computer module.

15. The method of claim 12, comprising entering content to be displayed by the modular, all-in-one computing device.
